(19) United States
(12) Patent Application Publication
(10) Pub. No.: US 2007/0187756 A1
(43) Pub. Date: Aug. 16, 2007

(54) Metal Source Power Transistor And Method Of Manufacture

(76) Inventor: John P. Snyder, Edina, MN (US)

Correspondence Address: DORSEY & WHITNEY LLP;INTELLECTUAL PROPERTY DEPARTMENT, SUITE 1500, 50 SOUTH SIXTH STREET, MINNEAPOLIS, MN, 55402-1498, US

(21) Appl. No.: 11/622,791

(22) Filed: Jan. 12, 2007

Related U.S. Application Data
(63) Continuation of application No. PCT/US05/25187, filed on Jul. 15, 2005.
(60) Provisional application No. 60/588,213, filed on Jul. 15, 2004.

(51) Int. Cl. H01L 29/76

(52) U.S. Cl. 257/343

(57) ABSTRACT

A metal source power transistor device and method of manufacture is provided, wherein the metal source power transistor having a source which is comprised of metal and which forms a Schottky barrier with the body region and channel region of the transistor. The metal source power transistor is unconditionally immune from parasitic bipolar action and, therefore, the effects of snap-back and latch-up, without the need for a body contact. The ability to allow the body to float in the metal source power transistor reduces the process complexity and allows for more compact device layout.

### CROSS-REFERENCE TO RELATED APPLICATION(S)

This application is a continuation of International application number PCT/US2005/025187, filed Jul. 15, 2005 which claims priority to U.S. Application No. 60/588,213 filed Jul. 15, 2004, the contents of both are herein incorporated in their entirety by reference.

### FIELD OF THE INVENTION

The present invention generally relates to the field of semiconductor power transistors. More particularly, the present invention relates to power metal oxide semiconductor (MOS) transistors and insulated gate bipolar transistors (IGBT) which include a metal source and do not require a body contact for mitigating/reducing parasitic bipolar action.

### BACKGROUND OF THE INVENTION

Conventional power transistors are semiconductor devices used for regulating and controlling voltages and currents in electronic devices and circuits. Two examples of conventional power transistors are the planar power MOS transistor and the vertical trench IGBT. FIG. 1 shows a cross-sectional view of a conventional planar power transistor 100.

Referencing FIG. 1, a conventional planar power MOS transistor 100 consists of a highly conductive substrate 101 which functions as the drain of the transistor. A moderately doped drift layer 102 is provided on top of the conductive substrate 101. Moderately doped body regions 103 are located in the drift layer 102 and highly doped source regions 104 are located within the body regions 103. A gate stack consisting of a gate insulator 106 and a gate electrode 105 is located over the body regions 103 and the drift layer 102. A highly doped body contact region 108 is provided to make an ohmic contact with the body contact electrode 109. For a conventional planar power MOS transistor 100, conduction takes place in an inversion layer generated in the body regions 103 just below the gate electrode 105 in a lateral path from the source regions 104 to the drift layer 102. Modulation of the current is accomplished by adjusting the voltage applied to the gate electrode 105.

One deleterious effect which arises in conventional power transistors is parasitic bipolar action. Undesirable parasitic bipolar action in power transistors is a direct consequence of the well-known bipolar gain phenomena in p+-n or n+-p junctions. Referencing FIG. 1, the undesirable parasitic bipolar transistor 112 is shown for clarity. For opposite doping concentrations that differ significantly (greater than an order of magnitude), majority carrier currents on the lightly doped side of the junction will trigger substantially larger majority carrier currents on the heavier doped side of the junction. This current gain is a result of the drift-diffusion charge transport mechanisms at work in a conventional p-n junction.

In a conventional power transistor, parasitic bipolar action is mitigated by ensuring adequate control of the potential of the body electrode or body contact. Stable body potentials prevent the body-source p-n junction, which has a large bipolar gain, from becoming forward biased. Snap-back and/or latch-up effects are thus avoided. In contrast, metal source power devices have negligible bipolar gains and therefore are not at risk of triggering these deleterious effects.

This body contact, while mitigating the effects of parasitic bipolar action, has the unfortunate consequence of increasing the cost per die. This cost increase is a result of additional processing steps necessary for fabricating the top-side body contacts and also the increased die size due to the silicon area consumed by the top-side body contacts.

There is a need in the industry to provide a power transistor that is unconditionally immune to parasitic bipolar action that does not require additional process steps, increased process and design complexity, and increased die size due to the necessity of providing a body contact, at the expense of process and design complexity and die size, and, therefore, provides performance, manufacturability and cost benefits as compared to alternative power transistor technologies.

### BRIEF SUMMARY OF THE INVENTION

In one aspect, the present invention provides a power transistor which is unconditionally immune from parasitic bipolar action which does not require a body contact.

In another aspect, the present invention provides a metal source power transistor comprising a semiconductor substrate forming a drain layer of a first conductivity type, a drift layer of a similar first conductivity type arranged on said drain layer, a body region of a second conductivity type arranged in said drift layer, a source region arranged in said body region, wherein said source region is formed from a metal and forms a Schottky contact to said body region; and a gate electrode arranged on said body region and said drift region.

In yet another aspect, the present invention provides a metal source power transistor comprising a semiconductor substrate forming an emitter layer of a first conductivity type, a drain layer of a second conductivity type arranged on said emitter layer, a drift layer of a similar second conductivity type arranged on said drain layer, a body region of a first conductivity type arranged in said drift layer, a source region arranged in said body region, wherein said source region is formed from a metal and forms a Schottky contact to said body region; and a gate electrode arranged on said body region and said drift region.

While multiple embodiments are disclosed, still other embodiments of the present invention will become apparent to those skilled in the art from the following detailed description, which shows and describes illustrative embodiments of the invention. As will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 illustrates a cross-sectional view of a conventional N-type planar power MOS transistor;

FIG. 2 illustrates a cross-sectional view of an exemplary embodiment of an N-type planar metal source power MOS transistor in accordance with the principles of the present invention;

FIG. 3 illustrates a cross-sectional view of an exemplary embodiment of an N-type planar metal source IGBT in accordance with the principles of the present invention;

FIG. 4 illustrates a cross-sectional view of an exemplary embodiment of an N-type vertical trench metal source power MOS transistor in accordance with the principles of the present invention;

FIG. 5 illustrates a cross-sectional view of an exemplary embodiment of an N-type vertical trench metal source IGBT in accordance with the principles of the present invention;

FIG. 6 illustrates an expanded cross-sectional view of the metal source, body region, and a thin interfacial layer interposed between the metal source and body region of a planar metal source power transistor, and

FIG. 7 illustrates an expanded cross-sectional view of the metal source, body region, and a thin interfacial layer interposed between the metal source and body region of a vertical trench metal source power transistor

### DETAILED DESCRIPTION

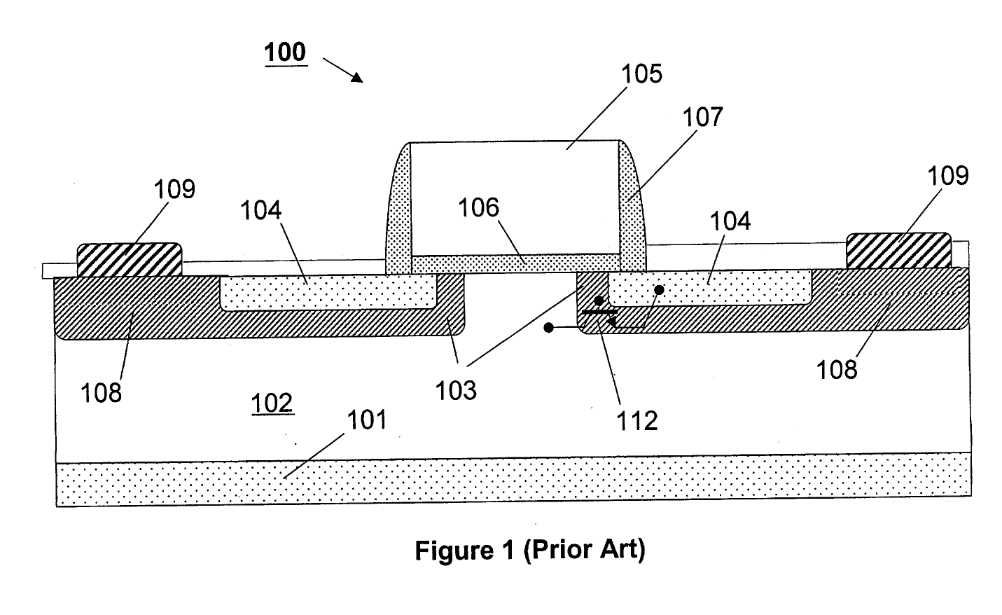

In general, the present invention provides a metal source power transistor. In one embodiment, the metal source power transistor is generally comprised of a semiconductor substrate containing a highly doped drain layer of first conductivity type, a moderately doped drift layer of first conductivity type, a moderately doped body region of second conductivity type, a metal source region, and a gate electrode on the semiconductor substrate. The metal source and the drift region define a channel region having a channel-length. The metal source forms a Schottky barrier to the body region and the channel. In contrast to the prior art as shown in FIG. 1, the metal source power transistor of the present invention does not include a body contact. Again, referencing FIG. 1, the body contact is comprised of both the highly doped ohmic contact region 108 and the body contact electrode 109.

A metal source power transistor in accordance with the principles of the present invention substantially eliminates parasitic bipolar action thereby making it unconditionally immune to latch-up, snapback effects, and other deleterious effects related to parasitic bipolar action, and, therefore, allows the body to float which eliminates the need to include a body contact. This unconditional immunity to parasitic bipolar action is present regardless of the voltage, doping profiles, or layout of the device. Also, the metal source power transistor of the present invention is easily manufacturable, having at least two fewer masks for source and body contact formation which is a reduction of approximately 35% for a five to six mask fabrication process. Also, the absence of topside body contacts allows for a more compact layout providing an area savings of approximately 25%.

In contrast to the prior art, the metal source power transistor of the present invention has no need for a highly conductive path to an ohmic contact to the body.

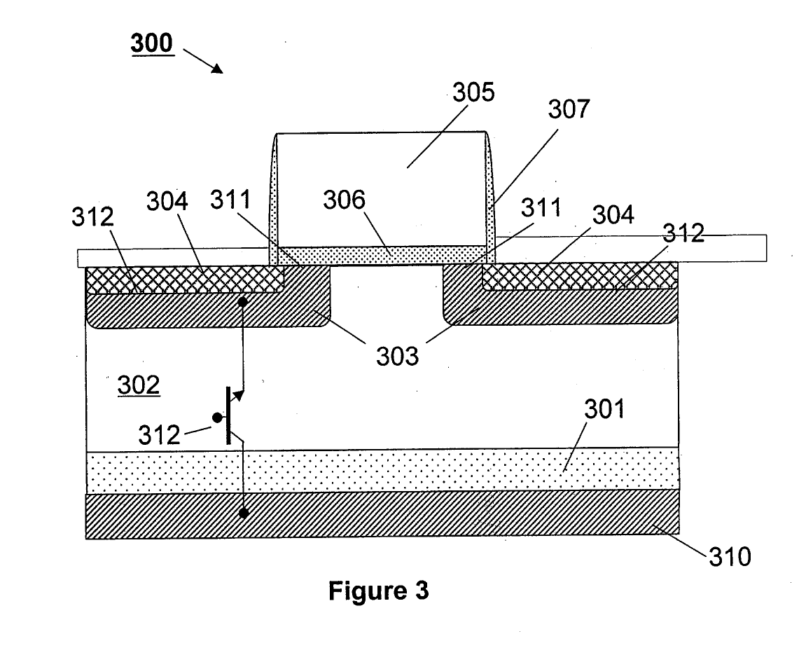

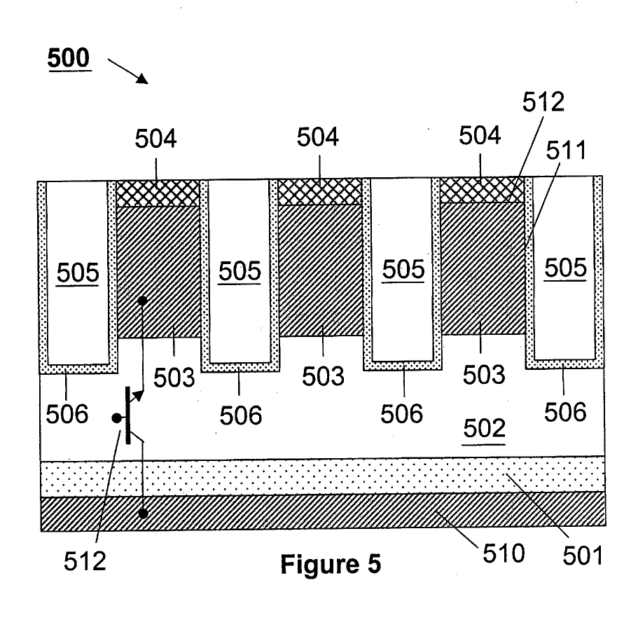

An exemplary embodiment of the present invention is a metal source IGBT device. It is appreciated that although there is unconditional elimination of the parasitic bipolar action in the metal source IGBT device, the bipolar action that is central to the operation of the device during normal operation is unaffected by the metal source and, therefore, operates as usual. For example, in a metal source N-type IGBT the undesirable parasitic bipolar NPN transistor is unconditionally eliminated, but the main bipolar PNP transistor that is necessary for proper device operation is present and largely unaffected. Similarly, for a metal source P-type IGBT, the undesirable parasitic PNP transistor is unconditionally eliminated and the main bipolar NPN transistor necessary for proper device operation is present and largely unaffected. Referencing FIGS. 3 and 5, the main bipolar transistor 312,512 that is necessary for proper device operation and in largely unaffected by the metal source is shown.

Another advantage of a metal source IGBT is that a floating body region will allow for MOS dynamic threshold voltage shift via the body effect. For example, for an N-type metal source IGBT, holes injected by the PNP bipolar will flood the body and raise its potential, thus lowering the threshold voltage of the N-type MOS device. This threshold voltage lowering then injects more electrons into the base of the PNP, which causes even more holes to flood the body. This positive feedback is self-limiting however, so that control of the device via the gate electrode is always maintained.

Yet another advantage of a metal source IGBT is that Schottky contacts may be used on the PNP bipolar of an N-type metal source IGBT and on the NPN bipolar of a P-type metal source IGBT as a means to enhance switching times.

Another exemplary embodiment of the present invention is a metal source power MOS transistor. For a metal source power MOS transistor, in the case where there is no ohmic contact to the body, no direct access to the body-drain diode exists and therefore an external protection diode may be required for certain applications.

Another advantage of a metal source power MOS transistor of the present invention is that by allowing the body to float, the body region may be appropriately biased to take advantage of MOS dynamic threshold shift due to the body effect which would result in enhanced drive current and a reduced “ON” state resistance. Also, the drift region of the metal source power MOS transistor may be arranged and configured to take advantage of current multiplication by means of impact ionization without any risk of turning on the parasitic bipolar transistor.

Throughout the discussion herein, there will be examples provided that make reference to a semiconductor substrate on which a metal source power transistor is formed. The present invention does not restrict the semiconductor substrate to any particular type. One skilled in the art will readily realize that many semiconductor substrates may be used for metal source power transistors including for example silicon, silicon germanium, gallium arsenide, indium phosphide, silicon carbide, gallium nitride, strained semiconductor substrates, and silicon on insulator (SOI). These substrate materials and any other semiconductor substrate may be used and are within the scope of the teachings of the present invention.

Throughout the discussion herein there will be examples provided that make reference to Schottky and Schottky-like barriers and contacts in regards to transistor fabrication. The present invention does not recognize any limitations in regards to what types of Schottky interfaces may be used in affecting the teachings of the present invention. Thus, the present invention specifically anticipates these types of contacts to be created with any form of conductive material or alloy.

Additionally, while traditional Schottky contacts are abrupt, the present invention specifically anticipates that in some circumstances an interfacial layer may be utilized between the silicon substrate and the metal. These interfacial layers may be ultra-thin, for example, having a thickness of approximately 10 m or less. Thus, the present invention specifically anticipates Schottky-like contacts and their equivalents to be useful in implementing the present invention. Furthermore, the interfacial layer may comprise materials that have conductive, semi-conductive, and/or insulator-like properties. For example, ultra-thin interfacial layers of oxide or nitride insulators may be used, or ultra-thin dopant layers formed by dopant segregation techniques may be used, or ultra-thin interfacial layers of a semiconductor, such as Germanium, may be used to form Schottky-like contacts, among others.

While the exemplary embodiments of the invention described herein are comprised of N-type metal source power MOS and N-type metal source IGBT devices, P-type metal source power MOS and P-type metal source IGBT devices can be realized by substituting the opposite polarity type for the impurity dopants and using an appropriate metal source material.

Planar Metal Source Power Transistor

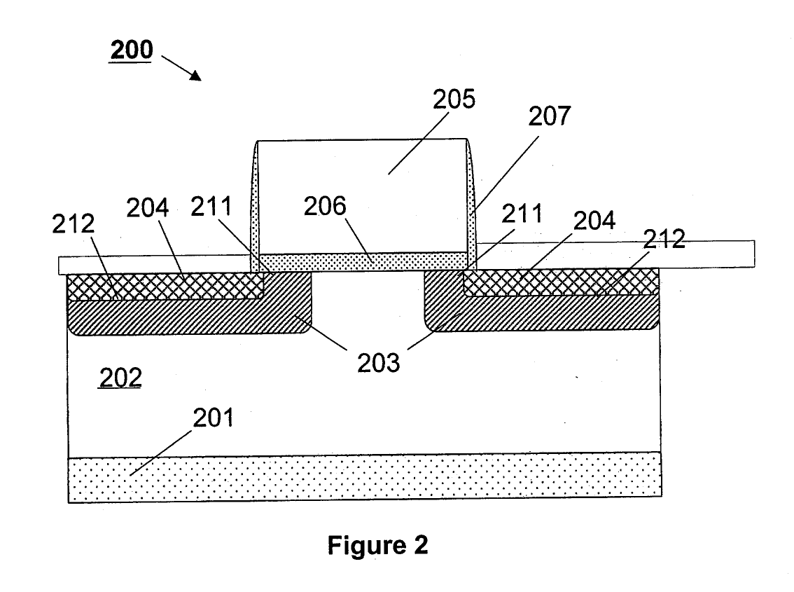

FIG. 2 shows a cross-sectional view of an exemplary embodiment of the invention as exemplified by a planar N-type metal source power MOS transistor 200. This embodiment comprises a substrate comprised of an N⁺ drain 201 and an N-type drift layer 202 epitaxially grown on top of the N⁺ drain 201. P-type body regions 203 are located in the N-type drift layer 202 and metal source regions 204 are located in the P-type body regions 203. The P-type body region 203 may be provided by dopant diffusion or implant into the N-type drift layer 202. For the planar N-type metal source power MOS transistor 200, the metal source regions 204 may be formed from a material that forms a low Schottky barrier to electrons from the group comprising Rare Earth Silicides such as Erbium Silicide, Dysprosium Silicide or Ytterbium Silicide, etc. or combinations thereof. For a planar P-type metal source power MOS transistor, the metal source regions may be formed from a material that forms a low Schottky barrier to holes from any one or a combination of Platinum Silicide, Palladium Silicide, Iridium Silicide and/or alloys thereof.

A channel region 211 is located laterally between the metal source regions 204 and the N-type drift layer 202. The channel region 211 is the on-state current-carrying region, wherein mobile charge carriers such as holes and electrons flow from the metal source regions 204 to the N-type drift layer 202. An insulating layer 206 is located on top of the channel regions 211 and the N-type drift layer 202. The insulating layer 206 is comprised of a material such as silicon dioxide. A gate electrode 205 is located on top of the insulating layer 206 and a thin insulating sidewall spacer 207 surrounds the gate electrode 205. The gate electrode 205 may be doped poly silicon, where Boron and Phosphorous dopants are used for the P-type and N-type metal source power MOS gate electrode, respectively. The gate electrode 205 may also be comprised of one or more metals.

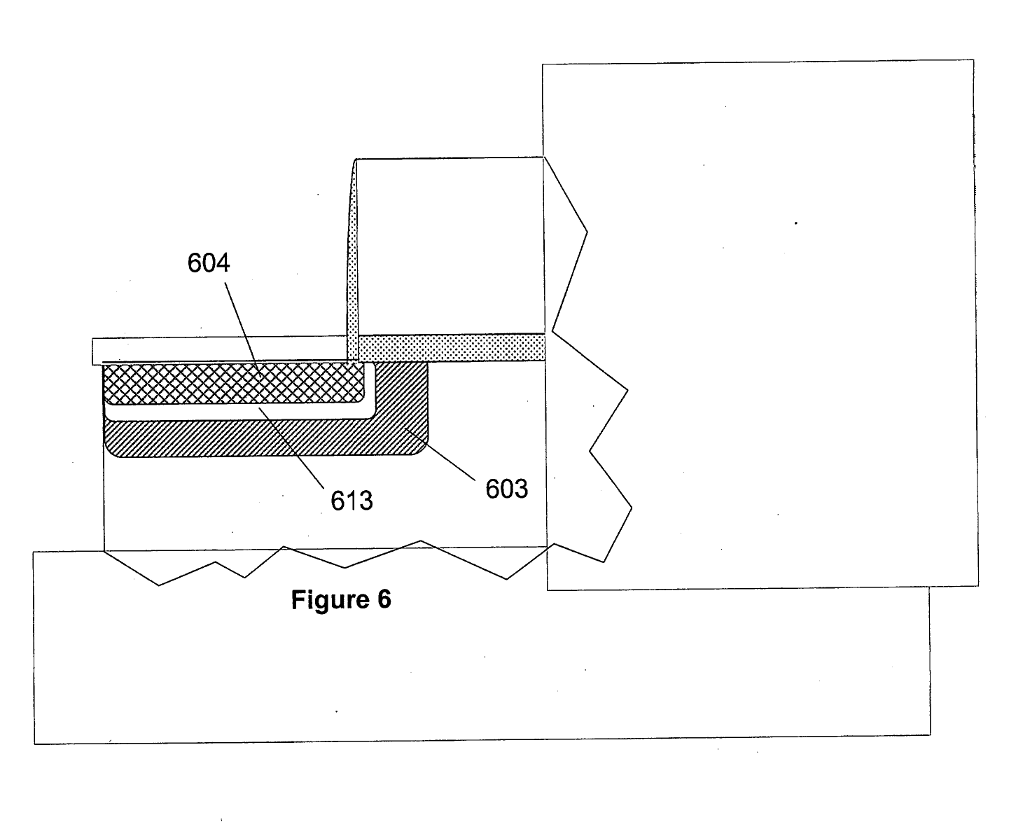

Referring again to FIG. 2, the metal source regions 204 are composed partially or fully of a metal. Because the metal source regions 204 are composed in part of a metal, they form Schottky or Schottky-like contacts 212 with the P-type body regions 203 and the channel regions 211. A Schottky contact is formed at the interface between a metal and a semiconductor, and a Schottky-like contact is formed by the close proximity of a metal and a semiconductor, wherein for example, the metal and the semiconductor are separated by approximately 0.1 to 10 nm. The Schottky contacts or Schottky-like contacts or junctions 212 may be provided by forming the metal source regions 204 from metal silicides. Schottky or Schottky-like contact or junctions 212 may also be formed by interposing a thin interfacial layer between the metal source regions 204 and the P-type body region 203. FIG. 6 shows an expanded cross-sectional view of the metal source region 604, body region 603, and a thin interfacial layer 613 interposed between the metal source region 604 and the body region 603 for a planer metal source power transistor. In another exemplary embodiment, the metal source regions 204 may also be composed of layered stacks of metals, wherein a first metal is provided in contact with the P-type body region 203, while additional metals may be used to cap or cover the top surface of the first metal.

FIG. 3 shows a cross-sectional view of another exemplary embodiment of the invention as exemplified by a planar N-type metal source IGBT 300. This embodiment comprises a substrate comprised of a P⁺ emitter 310 an N⁺ buffer layer 301 epitaxially grown on the P⁺ emitter and an N-type drift layer 302 epitaxially grown on top of the N⁺ buffer layer 301. P-type body regions 303 are located in the N-type drift layer 302 and metal source regions 304 are located in the P-type body regions 303. The P-type body region 303 may be provided by dopant diffusion or implant into the N-type drift layer 302. For the planar N-type metal source IGBT 300, the metal source regions 304 may be formed from a material that forms a low Schottky barrier to electrons from the group comprising Rare Earth Silicides, such as Erbium Silicide, Dysprosium Silicide or Ytterbium Silicide, etc., or combinations thereof. For a planar P-type metal source IGBT, the metal source regions may be formed from a material that forms a low Schottky barrier to holes from any one or a combination of Platinum Silicide, Palladium Silicide, Iridium Silicide and/or alloys thereof.

A channel region 311 is located laterally between the metal source regions 304 and the N-type drift layer 302. The channel region 311 is the on-state current-carrying region, wherein mobile charge carriers such as holes and electrons flow from the metal source regions 304 to the N-type drift layer 302. An insulating layer 306 is located on top of the channel regions 311 and the N-type drift layer 302. The insulating layer 306 is comprised of a material such as silicon dioxide. A gate electrode 305 is located on top of the insulating layer 306 and a thin insulating sidewall spacer 307 surrounds the gate electrode 305. The gate electrode 305 may be doped poly silicon, where Boron and Phosphorous dopants are used for the P-type and N-type metal source IGBT gate electrode, respectively. The gate electrode 305 may also be comprised of one or more metals.

Referring again to FIG. 3, the metal source regions 304 are composed partially or fully of a metal. Because the metal source regions 304 are composed in part of a metal, they form Schottky or Schottky-like contacts 312 with the P-type body regions 303 and the channel regions 311. A Schottky contact is formed at the interface between a metal and a semiconductor, and a Schottky-like contact is formed by the close proximity of a metal and a semiconductor, wherein for example, the metal and the semiconductor are separated by approximately 0.1 to 10 nm. The Schottky contacts or Schottky-like contacts or junctions 312 may be provided by forming the metal source regions 304 from metal suicides. Schottky or Schottky-like contact or junctions 312 may also be formed by interposing a thin interfacial layer between the metal source regions 304 and the P-type body region 303. FIG. 6 shows an expanded cross-sectional view of the metal source region 604, body region 603, and a thin interfacial layer 613 interposed between the metal source region 604 and the body region 603 for a planer metal source power transistor. In another exemplary embodiment, the metal source regions 304 may also be composed of layered stacks of metals, wherein a first metal is provided in contact with the P-type body region 303, while additional metals may be used to cap or cover the top surface of the first metal.

Planar Metal Source Power Transistor Process/Method

One exemplary process of fabrication of a planar metal source power transistor is described below with respect to FIGS. 2 and 3 for the fabrication of a metal source power MOS transistor or and metal source IGBT, respectively.

To begin, appropriate starting material is selected based on the type of device being fabricated. For an N-type planar metal source power MOS transistor 200, an N⁺ substrate 201 with an N-type drift layer 202 epitaxially grown on top of the N⁺ substrate 201 will be selected. For an N-type planar metal source IGBT 300, a P⁺ substrate 310 with an N⁺ buffer 301 epitaxially grown on the P⁺ emitter substrate 310 and an N-type drift layer 302 epitaxially grown on the N⁺ buffer 301 will be selected.

Then, an insulating layer to be used as the gate oxide 206,306 is grown on the N-type drift layer 202,302. The gate oxide growth is immediately followed by a doped silicon film. The film is doped with, for example, Phosphorous for an N-type device and Boron for a P-type device. Using lithographic techniques to pattern the gate electrode 205,305, a silicon etch that is highly selective to the oxide is used to remove the excess doped silicon film.

Next, using the gate electrode 205,305 as an implant mask, the P-type body regions 203,303 are provided by implantation of Boron dopants into the N-type drift layer 202,302.

A thin oxide is then thermally grown on the top surfaces and sidewalls of the silicon gate electrode 205,305. An anisotropic etch is then used to remove the thin oxide on the horizontal surfaces thereby exposing the silicon while preserving the thin sidewall oxides 207,307 on the gate electrode 205,305. In this way, a sidewall oxide spacer 207,307 is formed, and the dopants in the gate electrode 205,305 and the P-type body regions 203,303 are electrically activated.

The next step encompasses depositing an appropriate metal (for example, Erbium for the N-type device and Platinum for a P-type device) as a blanket film on all exposed surfaces. The wafer is then annealed for a specified time at a specified temperature (for example 45 minutes at 45° C.) so that, at all places where the metal is in direct contact with the silicon, a chemical reaction takes place that converts the metal to a metal silicide and forms the metal source 204,304. The metal that was in direct contact with a non-silicon surface is left unaffected.

A wet chemical etch (for example, aqua regia for Platinum, Sulfuric acid and hydrogen peroxide for Erbium) is then used to remove the unreacted metal while leaving the metal-silicide untouched. Accordingly, one exemplary planar metal source power transistor is now complete and ready for a standard backend metallization process.

It is appreciated that the above described process is one of many possible ways to form a planar metal source power transistor, and that suitable variants and alternatives may be used without departing from the scope of the present invention.

Vertical Metal Source Power Transistor

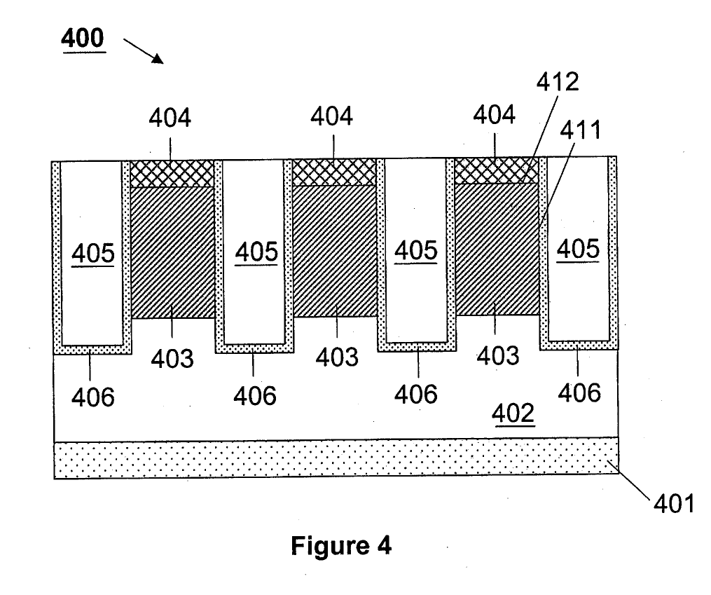

FIG. 4 shows a cross-sectional view of another exemplary embodiment of the invention as exemplified by a vertical trench N-type metal source power MOS transistor 400. This embodiment comprises a substrate comprised of an N⁺ drain layer 401, an N-type drift layer 402 epitaxially grown on top of the N⁺ drain layer 401, and a P-type body layer 403 epitaxially grown on the N-type drift layer 402. Deep trenches are provided which extend from the surface of the P-type body layer 403 into the N-type drift layer 402. The trenches are lined with an insulating layer 406 and filled with a conductive material to form a gate electrode 405. The insulating layer 406 is comprised of a material such as silicon dioxide. The gate electrode 405 may be doped poly silicon, where Boron and Phosphorous dopants are used for the P-type and N-type metal source power MOS gate electrode, respectively. The gate electrode 405 may also be comprised of one or more metals. The gate electrode 405 may be comprised of the same metals or different metals.

Metal source regions 404 are located on the top of the P-type body layer 403. For the vertical trench N-type metal source power MOS 400, the metal source regions 404 may be formed from a material that forms a low Schottky barrier to electrons from the group comprising Rare Earth Silicides, such as Erbium Silicide, Dysprosium Silicide or Ytterbium Silicide, etc., or combinations thereof. For a vertical trench P-type metal source power MOS, the metal source regions may be formed from a material that forms a low Schottky barrier to holes from any one or a combination of Platinum Silicide, Palladium Silicide, Iridium Silicide and/or alloys thereof.

A channel region 411 is located vertically between the metal source regions 404 and the N-type drift layer 402. The channel region 411 is the on-state current-carrying region, wherein mobile charge carriers such as holes and electrons flow from the metal source regions 404 to the N-type drift layer 402.

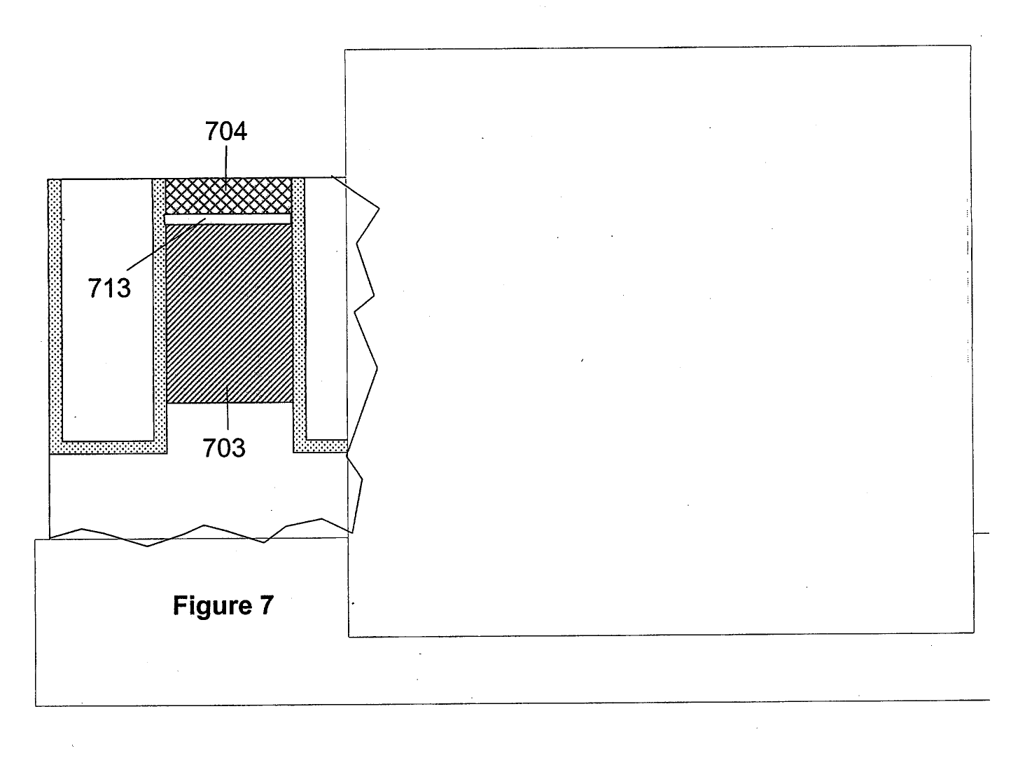

Referring again to FIG. 4, the metal source regions 404 are composed partially or fully of a metal. Because the metal source regions 404 are composed in part of a metal, they form Schottky or Schottky-like contacts 412 with the P-type body regions 403 and the channel regions 411. A Schottky contact is formed at the interface between a metal and a semiconductor, and a Schottky-like contact is formed by the close proximity of a metal and a semiconductor, wherein for example, the metal and the semiconductor are separated by approximately 0.1 to 10 nm. The Schottky contacts or Schottky-like contacts or junctions 412 may be provided by forming the metal source regions 404 from metal silicides. Schottky or Schottky-like contact or junctions 412 may also be formed by interposing a thin interfacial layer between the metal source regions 404 and the P-type body region 403. FIG. 7 shows an expanded cross-sectional view of the metal source region 704, body region 703, and a thin interfacial layer 713 interposed between the metal source region 704 and the body region 703 for a vertical trench metal source power transistor. In another exemplary embodiment, the metal source regions 404 may also be composed of layered stacks of metals, wherein a first metal is provided in contact with the P-type body region 403, while additional metals may be used to cap or cover the top surface of the first metal.

FIG. 5 shows a cross-sectional view of yet another exemplary embodiment of the invention as exemplified by a vertical trench N-type metal source IGBT 500. This embodiment comprises a substrate comprised of a P⁺ emitter 510 an N⁺ buffer layer 501 epitaxially grown on the P⁺ emitter 510 an N-type drift layer 502 epitaxially grown on top of the N⁺ drain layer 501 and a P-type body layer 503 epitaxially grown on the N-type drift layer 502. Deep trenches are provided which extend from the surface of the P-type body layer 503 into the N-type drift layer 502. The trenches are lined with an insulating layer 506 and filled with a conductive material to form a gate electrode 505. The insulating layer 506 is comprised of a material such as silicon dioxide. The gate electrode 505, may be doped poly silicon, where Boron and Phosphorous dopants are used for the P-type and N-type metal source IGBT gate electrode, respectively. The gate electrode 505 may also be comprised of one or more metals.

Metal source regions 504 are located on the top of the P-type body layer 503. For the vertical trench N-type metal source IGBT 500, the metal source regions 504 may be formed from a material that forms a low Schottky barrier to electrons from the group comprising Rare Earth Silicides, such as Erbium Silicide, Dysprosium Silicide or Ytterbium Silicide, etc., or combinations thereof. For a vertical trench P-type metal source IGBT the metal source regions may be formed from a material that forms a low Schottky barrier to holes from any one or a combination of Platinum Silicide, Palladium Silicide, Iridium Silicide and/or alloys thereof.

A channel region 511 is located vertically between the metal source regions 504 and the N-type drift layer 502. The channel region 511 is the on-state current-carrying region, wherein mobile charge carriers such as holes and electrons flow from the metal source regions 504 to the N-type drift layer 502.

Referring again to FIG. 5, the metal source regions 504 are composed partially or fully of a metal. Because the metal source regions 504 are composed in part of a metal, they form Schottky or Schottky-like contacts 512 with the P-type body regions 503 and the channel regions 511. A Schottky contact is formed at the interface between a metal and a semiconductor, and a Schottky-like contact is formed by the close proximity of a metal and a semiconductor, wherein for example, the metal and the semiconductor are separated by approximately 0.1 to 10 nm. The Schottky contacts or Schottky-like contacts or junctions 512 may be provided by forming the metal source regions 504 from metal silicides. Schottky or Schottky-like contact or junctions 512 may also be formed by interposing a thin interfacial layer between the metal source regions 504 and the P-type body region 503. FIG. 7 shows an expanded cross-sectional view of the metal source region 704, body region 703, and a thin interfacial layer 713 interposed between the metal source region 704 and the body region 703 for a vertical trench metal source power transistor. In another exemplary embodiment, the metal source regions 504 may also be composed of layered stacks of metals, wherein a first metal is provided in contact with the P-type body region 503, while additional metals may be used to cap or cover the top surface of the first metal.

Vertical Trench Metal Source Power Transistor Process/Method

One exemplary process of fabrication of a vertical trench metal source power transistor is described below with respect to FIGS. 4 and 5 for the fabrication of a metal source power MOS transistor or and metal source IGBT, respectively.

To begin, appropriate starting material is selected based on the type of device being fabricated. For an N-type vertical trench metal source power MOS transistor 400, an N⁺ substrate 401 with an N-type drift layer 402 epitaxially grown on top of the substrate 401, and a P-type body layer 403 epitaxially grown on the N-type drift layer 402 will be selected. For an N-type vertical trench metal source IGBT 500, a P⁺ substrate 510 with an N⁺ buffer 501 epitaxially grown on the P⁺ emitter 510 and an N-type drift layer 502 epitaxially grown on the N⁺ buffer 501 and a P-type body layer 503 epitaxially grown on the N-type drift layer 502 will be selected.

Next, using lithographic techniques and an anisotropic silicon etch, deep trenches are etched into the silicon, extending from the top of the P-type body layer 403,503 into the N-type drift layer 402,502.

Following the trench etch, an oxide is grown on all surfaces of the trench to provide the gate insulator 406,506. Immediately following the gate oxide growth, the trenches are filled by the deposition of an in-situ doped silicon film to provide the gate electrode 405,505. The silicon film is in-situ doped with, for example, Phosphorous for an N-type device and Boron for a P-type device. Excess doped-silicon located beyond the surface of the P-type body layer is removed using a standard CMP process.

The next step encompasses depositing an appropriate metal (for example, Erbium for the N-type device and Platinum for a P-type device) as a blanket film on the surface. The wafer is then annealed for a specified time at a specified temperature (for example 45 minutes at 45° C.) so that, at all places where the metal is in direct contact with the silicon, a chemical reaction takes place that converts the metal to a metal silicide and forms the metal source 204,304. The metal that was in direct contact with a non-silicon surface is left unaffected.

A wet chemical etch (for example, aqua regia for Platinum, Sulfuric acid and Hydrogen Peroxide for Erbium) is then used to remove the unreacted metal while leaving the metal-silicide untouched. Accordingly, one exemplary vertical trench metal source power transistor is now complete and ready for a standard backend metallization process.

It is appreciated that the above described process is one of many possible ways to form a planar metal source power transistor, and that suitable variants and alternatives may be used without departing from the scope of the present invention.

Although the present invention has been described with reference to preferred embodiments, persons skilled in the art will recognize that changes may be made in form and detail without departing from the spirit and scope of the invention. The present invention may apply to any suitable use of metal source power transistor technology, whether it employs a Si substrate, SiGe substrate, GaAs substrate, GaN substrate, SiC substrate and metal gates. This list is not limitive. Any power transistor device for regulating the flow of electric current that employs metal source may have the benefits taught herein.

I claim:

1. A metal source power transistor comprising:
a semiconductor substrate forming a drain layer of a first conductivity type;
a drift layer of a similar first conductivity type arranged on said drain layer;
a body region of a second conductivity type arranged in said drift layer;
a source region arranged in said body region, wherein said source region is formed from a metal and forms a Schottky contact to said body region; and
a gate electrode arranged on said body region and said drift region.

2. The transistor of claim 1 wherein said drain layer is comprised of N+ silicon, said drift layer is comprised of epitaxially grown N-type silicon, said body region is comprised of P-type silicon, and said source region is formed of rare-earth silicides.

3. The transistor of claim 1 wherein said drain layer is comprised of P+ silicon, said drift layer is comprised of epitaxially grown P-type silicon, said body region is comprised of N-type silicon, and said source region is formed of any one or combination of Platinum Silicide, Palladium Silicide or Iridium Silicide.

4. The transistor of claim 1 wherein said metal source power transistor is a planar power MOS transistor.

5. A metal source power transistor comprising:
a semiconductor substrate forming an emitter layer of a first conductivity type;
a drain layer of a second conductivity type arranged on said emitter layer;
a drift layer of a similar second conductivity type arranged on said drain layer;
a body region of a first conductivity type arranged in said drift layer;
a source region arranged in said body region, wherein said source region is formed from a metal and forms a Schottky contact to said body region; and
a gate electrode arranged on said body region and said drift region.

6. The transistor of claim 1 wherein said emitter layer is comprised of P+ silicon, said drain layer is comprised of epitaxially grown N+ silicon, said drift layer is comprised of epitaxially grown N-type silicon, said body region is comprised of P-type silicon, and said source region is formed of rare-earth silicides.

7. The transistor of claim 1 wherein said emitter layer is comprised of N+ silicon, said drain layer is comprised of epitaxially grown P+ silicon, said drift layer is comprised of epitaxially grown P-type silicon, said body region is comprised of N-type silicon, and said source region is formed of any one or combination of Platinum Silicide, Palladium Silicide or Iridium Silicide.

8. The transistor of claim 1 wherein said metal source power transistor is a planar metal source IGBT.
